(19) United States
(12) Patent Application Publication
(10) Pub. No.: US 2012/0255593 A1
(43) Pub. Date: Oct. 11, 2012

(54) DYE-SENSITIZED SOLAR CELL MODULE

(75) Inventors: Kenta SEKIKAWA, Tokyo-to (JP); Satoshi MITSUDUKA, Tokyo-to (JP); Miho SASAKI, Tokyo-to (JP)

(73) Assignee: DAI NIPPON PRINTING CO., LTD., Tokyo-to (JP)

(21) Appl. No.: 13/439,125

(22) Filed: Apr. 4, 2012

(30) Foreign Application Priority Data
Apr. 7, 2011 (JP) 2011-085646

(51) Int. Cl. H01L 31/05

(52) U.S. Cl. 136/244

(57) ABSTRACT

The present invention relates to a dye-sensitized solar cell module that can appropriately prevent the occurrence of internal short-circuit in its individual dye-sensitized solar cells and which achieves high power generation efficiency, and has excellent workability. The solar cell module is structured such that contact between the first and second electrode layers in any one of the dye-sensitized solar cells is prevented and therefore internal short-circuit is less likely to occur. Further, the use of such dye-sensitized solar cells makes it possible for the dye-sensitized solar cell module according to the present invention to achieve high performance.

### TECHNICAL FIELD

The present invention relates to a dye-sensitized solar cell module that prevents the occurrence of internal short-circuit in its individual dye-sensitized solar cells, achieves high power generation efficiency, and has excellent workability.

2. Background Art

In recent years, environmental issues such as global warming believed to be caused by an increase in carbon dioxide have become serious, and therefore measures against such environmental issues have been taken worldwide. Particularly, solar cells utilizing the energy of sunlight have been actively researched and developed as environmentally-friendly clean energy sources. As such solar cells, monocrystalline silicon solar cells, polycrystalline silicon solar cells, amorphous silicon solar cells, and compound-semiconductor solar cells have already been practically used. However, these solar cells have problems such as high production cost. Under the circumstances, dye-sensitized solar cells have received attention and have been researched and developed as solar cells that are environmentally friendly and can be produced at lower cost.

A common dye-sensitized solar cell comprises, for example, a pair of electrode base materials that function as electrodes, a porous layer provided between the pair of electrode base materials and containing a dye-sensitizer-supported fine particle of a metal oxide semiconductor, and an electrolyte layer provided between the pair of electrode base materials so as to come into contact with the porous layer and having an electrolyte containing a redox couple. It is to be noted that, in such a dye-sensitized solar cell, at least one of the electrode base materials functions as a light-receiving surface that receives sunlight, and therefore has transparency.

An example of the electrolyte layer is one formed by filling a space created by the pair of electrode base materials and a sealing member provided between the pair of electrode base materials with a liquid electrolyte. The sealing member used for forming the electrolyte layer has not only the function of holding the liquid electrolyte together with the pair of electrode base materials but also the function of preventing internal short-circuit from occurring in the dye-sensitized solar cell due to the contact between the pair of electrode base materials.

In order to put such a dye-sensitized solar cell into practical use, a higher output voltage needs to be achieved. Therefore, attempts have been made to produce a dye-sensitized solar cell module in which a plurality of dye-sensitized solar cells is connected to each other.

Such a dye-sensitized solar cell module is affected as a whole when internal short-circuit occurs in one of the dye-sensitized solar cells thereof, and therefore prevention of the occurrence of internal short-circuit in its individual dye-sensitized solar cells is one of important issues.

Meanwhile, such a dye-sensitized solar cell module is required to have a structure that allows it to have high flexibility to improve its workability.

An example of a conventional structure of a dye-sensitized solar cell module having flexibility is one in which a plurality of dye-sensitized solar cells are provided between two base materials having flexibility.

However, when a dye-sensitized solar cell module having such a structure is subjected to bending work, there is a case where it is difficult to achieve desired bendability due to the difference in curvature between two base materials having flexibility or there is a problem that the dye-sensitized solar cell module is degraded by bending work.

Under the circumstances, Patent Document 1 discloses a structure of a dye-sensitized solar cell module, comprising: a first electrode base material having one first base material and a plurality of first electrode layers provided on the first base material; a plurality of second electrode base materials each having a second electrode layer; a plurality of porous layers provided between the first electrode layers provided on the first electrode base material and the second electrode layers of the second electrode base materials; a plurality of sealing members provided around the first electrode layers and the second electrode layers; and a plurality of electrolyte layers provided by filling spaces created by the first electrode layers, the second electrode layers, and the sealing members with a liquid electrolyte. A dye-sensitized solar cell module having such a structure can have high flexibility because the first electrode layers provided on the first electrode base material face their corresponding second electrode layers of the second electrode base materials.

However, production of a dye-sensitized solar cell module having such a structure requires the process of injecting an electrolyte after the first electrode base material and the second electrode base materials are bonded together, and therefore involves a problem that it takes time to produce large-area cells. Further, a dye-sensitized solar cell module having such a structure needs to have attachment portions, insulating portions, etc. to bond the first electrode base material and the second electrode base materials together. However, such attachment portions, insulating portions, etc. do not contribute to power generation, and therefore the power generation area of the dye-sensitized solar cell module is reduced as a whole. This becomes a factor in reducing power generation efficiency and causes a problem that materials such as base materials are excessively used. Further, there is a case where it is difficult to adequately inject an electrolyte into the spaces described above due to the flexure of the electrode base materials.

Further, a dye-sensitized solar cell module having such a structure has high flexibility, and therefore has a problem that, in its individual dye-sensitized solar cells, the first and second electrode layers sometimes come into contact with each other during use even when the sealing member is provided around these electrode layers so that internal short-circuit occurs.

Under the circumstances, there is a demand for a structure that allows a dye-sensitized solar cell module to have high flexibility and to effectively prevent the occurrence of internal short-circuit in its individual dye-sensitized solar cells.

### CITATION LIST

### Patent Literatures

Patent Literature 1: Japanese Patent Application Laid-Open No. 2006-032110

### SUMMARY OF INVENTION

### Technical Problem

In view of the above circumstances, it is a major object of the present invention to provide a dye-sensitized solar cell module that can appropriately prevent the occurrence of internal short-circuit in its individual dye-sensitized solar cells, achieves high power generation efficiency, and has excellent workability.

### Solution to Problem

In order to achieve the above object, the present invention provides a dye-sensitized solar cell module comprising: a first electrode base material having one first base material and a plurality of first electrode layers formed in a pattern on the first base material; a plurality of second electrode base materials each having at least a second electrode layer; a plurality of porous layers provided either on the first electrode layers of the first electrode base material or on the second electrode layers of the second electrode base materials and containing a dye-sensitizer-supported fine particle of a metal oxide semiconductor; and a plurality of solid electrolyte layers provided between the porous layers and the first electrode layers of the first electrode base material or the second electrode layers of the second electrode base materials, on which the porous layers are not provided, and containing a redox couple, wherein a plurality of dye-sensitized solar cells each comprising the first electrode layer, the second electrode layer, the porous layer, and the solid electrolyte layer are connected to each other so that the first electrode layer of one of the adjacent dye-sensitized solar cells and the second electrode layer of another of the adjacent dye-sensitized solar cells are electrically connected to each other, and wherein the dye-sensitized solar cells have, on an outside of an end of the first electrode layer of the first electrode base material, an end region including the first base material, the solid electrolyte layer, and the second electrode layer.

According to the present invention, in each of the end regions in the dye-sensitized solar cells, the first and second electrode layers do not face each other due to the absence of the first electrode layer, and in addition, the solid electrolyte layer is provided. This makes it possible to appropriately prevent the contact between the first and second electrode layers in any one of the dye-sensitized solar cells, and therefore internal short-circuit is less likely to occur in the dye-sensitized solar cells. Further, the use of such dye-sensitized solar cells makes it possible for the dye-sensitized solar cell module according to the present invention to achieve high performance.

In the present invention, it is preferred that, in each of the end regions, the solid electrolyte layer is provided at the end of the second electrode layer. In the dye-sensitized solar cells, internal short-circuit caused by the contact between the end of the first electrode layer and the end of the second electrode layer is likely to occur. Therefore, by providing the solid electrolyte layer at the end of the second electrode layer, it is possible to more effectively prevent the occurrence of internal short-circuit in the dye-sensitized solar cells, thereby further enhancing the performance of the dye-sensitized solar cell module according to the present invention.

In the present invention, it is also preferred that the solid electrolyte layers are larger in width than the first electrode layers. This makes it possible to provide the solid electrolyte layers having a sufficient area on the first electrode layers and therefore to sufficiently increase the power generation area of the dye-sensitized solar cells, thereby further enhancing the performance of the dye-sensitized solar cell module according to the present invention.

### Advantageous Effects of Invention

The dye-sensitized solar cell module according to the present invention is constituted from the dye-sensitized solar cells having the end region and therefore can prevent the occurrence of internal short-circuit in its individual dye-sensitized solar cells.

### BRIEF DESCRIPTION OF DRAWINGS

FIGS. 1A to 1C are each a schematic diagram of one example of a dye-sensitized solar cell module according to the present invention.

FIGS. 2A to 2C are each a schematic diagram of another example of the dye-sensitized solar cell module according to the present invention.

FIGS. 3A and 3B are each a schematic sectional view of yet another example of the dye-sensitized soar cell module according to the present invention.

FIGS. 4A and 4B are each a schematic plan view of one example of a first electrode base material used in the dye-sensitized solar cell module according to the present invention.

FIG. 5 is a schematic plan view of another example of the first electrode base material used in the dye-sensitized solar cell module according to the present invention.

FIGS. 6A to 6D show a step diagram showing one example of a first electrode base material-forming step in a method for producing the dye-sensitized solar cell module according to the present invention.

FIGS. 7A to 7E show a step diagram showing examples of a second electrode base material substrate preparation step, a porous layer-forming step, a solid electrolyte layer-forming step, and a cutting step in the method for producing the dye-sensitized solar cell module according to the present invention.

FIGS. 8A to 8C are each a schematic diagram showing the shape of a dye-sensitized solar cell module of Example 1 according to the present invention etc.

### DESCRIPTION OF EMBODIMENTS

Hereinbelow, a dye-sensitized solar cell module according to the present invention will be described.

The dye-sensitized solar cell module according to the present invention comprises: a first electrode base material having one first base material and a plurality of first electrode layers formed in a pattern on the first base material; a plurality of second electrode base materials each having at least a second electrode layer; a plurality of porous layers provided either on the first electrode layers of the first electrode base material or on the second electrode layers of the second electrode base materials and containing a dye-sensitizer-supported fine particle of a metal oxide semiconductor; and a plurality of solid electrolyte layers provided between the porous layers and the first electrode layers of the first electrode base material or the second electrode layers of the second electrode base materials, on which the porous layers are not provided, and containing a redox couple, wherein a plurality of dye-sensitized solar cells each comprising the first electrode layer, the second electrode layer, the porous layer, and the solid electrolyte layer are connected to each other so that the first electrode layer of one of the adjacent dye-sensitized solar cells and the second electrode layer of the other of the adjacent dye-sensitized solar cells are electrically connected to each other, and wherein the dye-sensitized solar cells have, on the outside of the end of the first electrode layer of the first electrode base material, an end region including the first base material, the solid electrolyte layer, and the second electrode layer.

It is to be noted that, in the dye-sensitized solar cell module according to the present invention, at least the first electrode base material or each of the second electrode base materials functions as a light-receiving surface that receives sunlight. Therefore, in the present invention, a base material with transparency is usually used as at least the first electrode base material or each of the second electrode base materials.

Here, the transparency of the “base material with transparency” is not particularly limited as long as the base material with transparency can transmit sunlight so that the dye-sensitized solar cell module according to the present invention can receive sunlight to perform its function. However the total light transmittance of the base material with transparency is preferably 50% or more. It is to be noted that the above transparency is measured by a measuring method specified in JIS K7361-1:1997.

In the dye-sensitized solar cell module according to the present invention, the first electrode layers or the second electrode layers, on which the porous layers are provided, are usually used as oxide semiconductor electrode layers, and the other electrode layers, on which the porous layers are not provided, are usually used as counter electrode layers.

The phrase “provided on the electrode layers” in the present invention conceptually includes not only direct formation on the first electrode layers or the second electrode layers but also formation on other layers provided on the first electrode layers or the second electrode layers.

Here, the dye-sensitized solar cell module according to the present invention will be described with reference to the accompanying drawings.

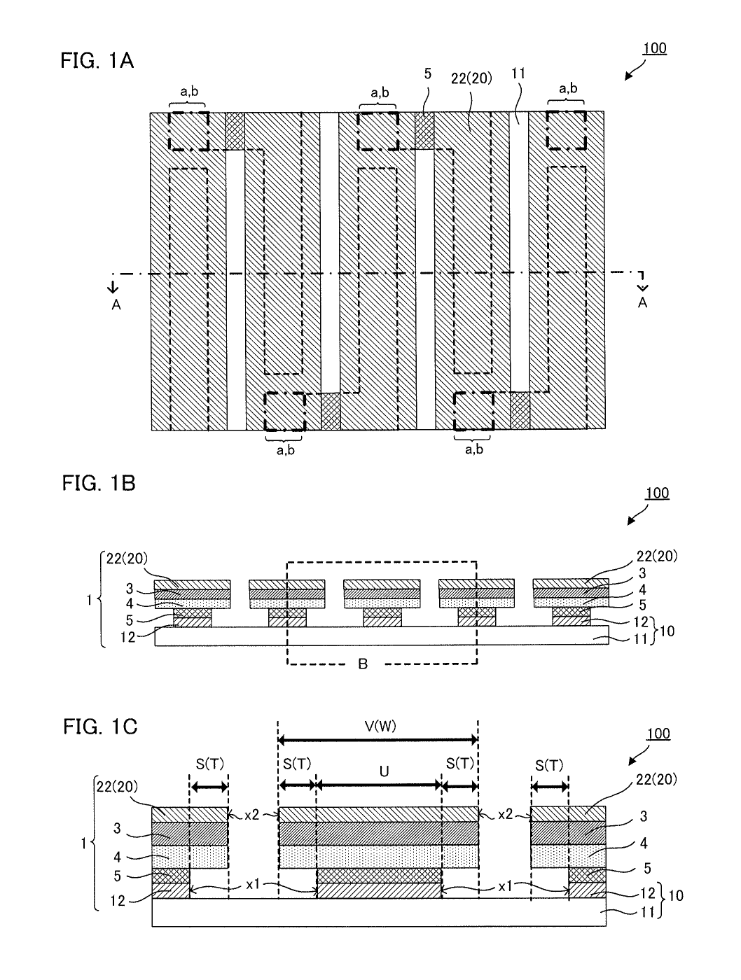

FIG. 1A is a schematic plan view of one example of the dye-sensitized solar cell module according to the present invention, FIG. 1B is a sectional view taken along the line A-A in FIG. 1A, and FIG. 1C is an enlarged view of the part B in FIG. 1B. It is to be noted that, in FIG. 1A, a region in which each of the first electrode layers is provided is indicated by a dotted line.

First, as shown in FIGS. 1A and 1B, a dye-sensitized solar cell module 100 according to the present invention comprises: a first electrode base material 10 having one first base material 11 and a plurality of first electrode layers 12 formed in a pattern on the first base material 11, a plurality of second electrode base materials 20 each having a second electrode layer 22, a plurality of porous layers 3 provided on the surfaces of the second electrode layers 22 and containing a dye-sensitizer-supported fine particle of a metal oxide semiconductor, and a plurality of solid electrolyte layers 4 provided between the porous layers 3 and the first electrode layers 12 and containing a redox couple. In the present invention, a plurality of catalyst layers 5 may be provided between the first electrode layers 12 and the solid electrolyte layers 4.

Although not shown, in the present invention, the porous layers may be provided on the surfaces of the first electrode layers.

As shown in FIGS. 1A and 1B, in the dye-sensitized solar cell module 100 according to the present invention, a plurality of dye-sensitized solar cells 1 each comprising the first electrode layer 12, the catalyst layer 5, the solid electrolyte layer 4, the porous layer 3, and the second electrode layer 22 are connected to each other so that the first electrode layer 12 of one of the adjacent dye-sensitized solar cells 1 and the second electrode layer 22 of the other of the adjacent dye-sensitized solar cells 1 are electrically connected to each other. It is to be noted that in the example shown in FIG. 1A, the first electrode layers 12 and the second electrode layers 22 are connected to each other inside the dye-sensitized solar cell module 100 in connection portions “a” each including the edge of short side of each of the stripes of the first electrode layers 12 formed in a stripe shape and in connection portions “b” each including the edge of short side of strip of each of the second electrode layers 22 formed in a strip shape (i.e., in portions indicated by alternate long and short dashed lines in FIG. 1A).

As shown in FIG. 10, in the dye-sensitized solar cell module 100 according to the present invention, the dye-sensitized solar cells 1 have, on the outside of an edge x1 of the first electrode layer 12 of the first electrode base material 10, an end region S including the first base material 11, the solid electrolyte layer 4, and the second electrode layer 22.

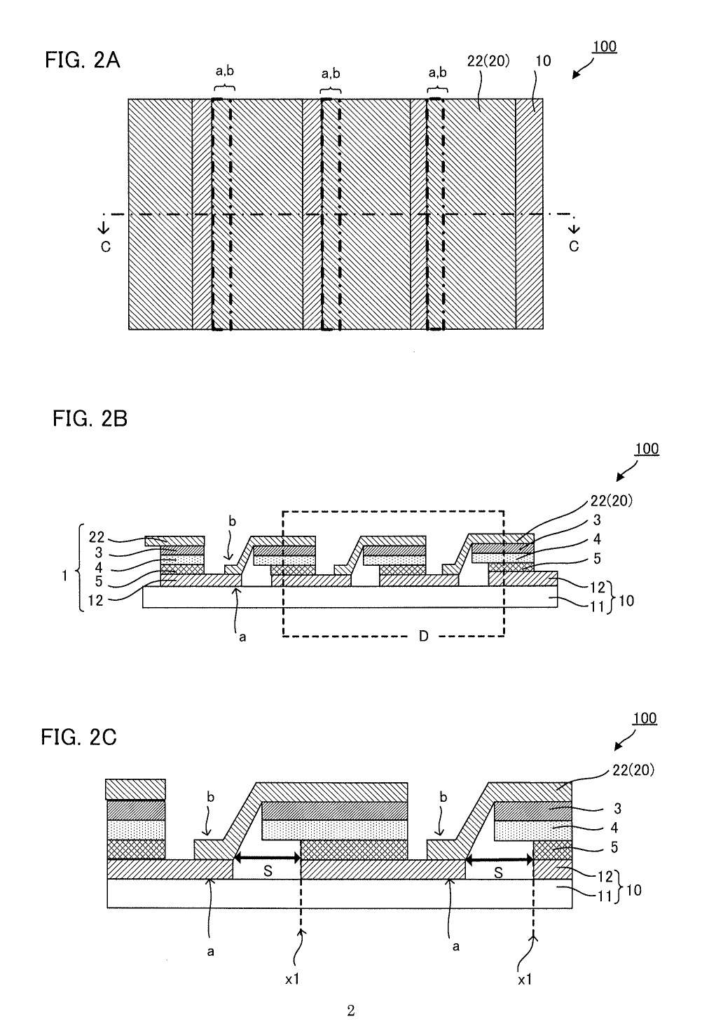

FIG. 2A is a schematic plan view of another example of the dye-sensitized solar cell module according to the present invention, FIG. 2B is a sectional view taken along the line C-C in FIG. 2A, and FIG. 2C is an enlarged view of the part D in FIG. 2B.

In the example shown in FIGS. 2A and 2B, the first electrode layers 12 and the second electrode layers 22 are connected to each other inside the dye-sensitized solar cell module 100 in the connection portions “a” each including the edge of long side of each of the stripes of the first electrode layers 12 and in the connection portions “b” each including the edge of long side of strip of each of the second electrode layers 22.

In this case, as shown in FIG. 2C, each of the end regions S is provided on the outside of the edge x1 of one of the two long sides opposite to the edge of the other long side of the first electrode layer 12 along which the connection portion “a” is provided.

It is to be noted that the reference numerals shown in FIGS. 2A to 2C but not described here are the same as those described above with reference to FIGS. 1A to 1C, and therefore a description thereof will not be repeated.

According to the present invention, in each of the end regions in the dye-sensitized solar cells, the first and second electrode layers do not face each other due to the absence of the first electrode layer, and in addition, the solid electrolyte layer is provided. This makes it possible to appropriately prevent the contact between the first electrode layer and the second electrode layer in any one of the dye-sensitized solar cells, and therefore internal short-circuit is less likely to occur in the dye-sensitized solar cells. Further, the use of such dye-sensitized solar cells makes it possible for the dye-sensitized solar cell module according to the present invention to achieve high performance.

Further, according to the present invention, the solid electrolyte layers are provided, and therefore it is possible to eliminate the necessity of using sealing members or the like used in a conventional dye-sensitized solar cell module to seal a liquid electrolyte. This makes it possible to increase the power generation area of the dye-sensitized solar cell module according to the present invention and to simplify the production process of the dye-sensitized solar cell module according to the present invention. Therefore, the dye-sensitized solar cell module according to the present invention can achieve high power generation efficiency and high productivity.

Hereinbelow, the dye-sensitized solar cell module according to the present invention will be described in detail.

I. End Regions

In the dye-sensitized solar cell module according to the present invention, the dye-sensitized solar cells have, on the outside of the end of the first electrode layer, the end region including the first base material, the solid electrolyte layer, and the second electrode layer.

Here, in the present invention, the dye-sensitized solar cells are provided on the first base material, and therefore the first base material is usually provided in the entire end regions.

Each of the end regions includes a region extending from the end of the first electrode layer to the end of the second electrode layer provided on the outside of the end of the first electrode layer, that is, a region where the first electrode layer and the second electrode layer do not face each other (hereinafter, simply referred to as an “electrode layer non-facing region”).

In each of the end regions, the solid electrolyte layer may be provided in any position between the first base material and the second electrode layer provided on the outside of the end of the first electrode layer.

Hereinbelow, the position of the solid electrolyte layer in each of the end regions will be described.

1. Position of Solid Electrolyte Layer

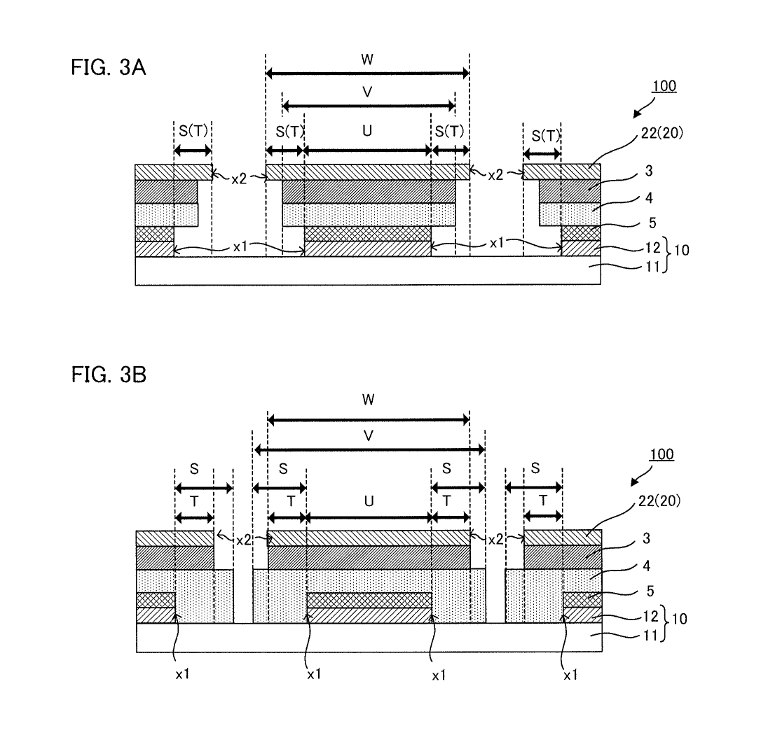

The position of the solid electrolyte layer in each of the end regions is not particularly limited as long as the solid electrolyte layer can be provided on the outside of the end of the first electrode layer and between the first base material and the second electrode layer. More specifically, as shown in FIG. 3A, the solid electrolyte layer 4 in each of the end regions S may be provided in a region located inside the electrode layer non-facing region T, that is, a region extending from the edge x1 of the first electrode layer 12 to an edge x2 of the second electrode layer 22 provided on the outside of the edge x1 of the first electrode layer 12. Alternatively, as shown in FIG. 1C, the solid electrolyte layer 4 in each of the end regions S may be provided in the electrode layer non-facing region T or, as shown in FIG. 3B, the solid electrolyte layer 4 in each of the end regions S may be provided in a region including the electrode layer non-facing region T and the outside of the region T.

Here, in the present invention, it is preferred that in each of the end regions, the solid electrolyte layer is provided at the end of the second electrode layer. In the dye-sensitized solar cells, internal short-circuit caused by the contact between the end of the first electrode layer and the end of the second electrode layer is likely to occur. Therefore, by providing the solid electrolyte layer at the end of the second electrode layer, it is possible to more effectively prevent the occurrence of internal short-circuit in the dye-sensitized solar cells, thereby further enhancing the performance of the dye-sensitized solar cell module according to the present invention.

It is to be noted that the phrase “the solid electrolyte layer is provided at the end of the second electrode layer” in the present invention means that the solid electrolyte layer is provided in such a manner that the end of the solid electrolyte layer is present in a region extending from 1 mm inside the end of the second electrode layer to 1 mm outside the end of the second electrode layer.

Therefore, the solid electrolyte layer 4 in each of the end regions S is preferably provided at at least the end of the second electrode layer. More specifically, as shown in FIG. 1C, the solid electrolyte layer 4 in each of the end regions S is preferably provided in the electrode layer non-facing region T or, as shown in FIG. 3B, in a region including the electrode layer non-facing region T and the outside of the region T.

The position of each of the solid electrolyte layers provided on the outside of the first electrode layers in planar view is not particularly limited as long as the end regions can be provided in at least part of the outside of the first electrode layers of the dye-sensitized solar cells provided in the present invention, and is therefore appropriately selected depending on the position of each of the end regions in planar view.

More specifically, when the dye-sensitized solar cells provided in the present invention are seen in planar view, the solid electrolyte layers may be provided in the electrode layer non-facing regions either continuously or in a predetermined pattern.

2. Position of End Region in Planar View

Hereinbelow, the position of each of the end regions in planar view will be described.

In the present invention, the position of each of the end regions in planar view is not particularly limited as long as the solid electrolyte layer and the second electrode layer can be provided on the first base material provided on the outside of the end of the first electrode layer and the occurrence of internal short-circuit in the dye-sensitized solar cells can be prevented. Therefore, the position of each of the end regions in planar view is usually appropriately selected depending on factors such as the pattern shape of each of the first electrode layers.

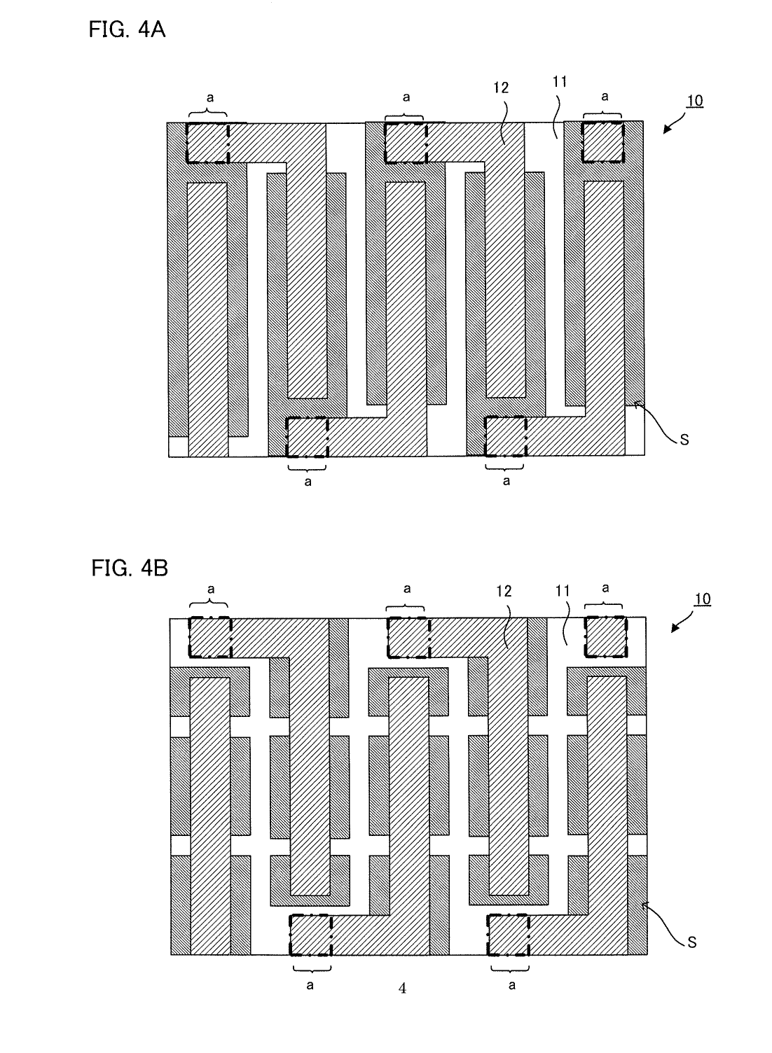

For example, as shown in FIG. 4A, each of the end regions S may be continuously provided along the end of the first electrode layer 12, or as shown in FIG. 4B, each of the end regions S may be provided discontinuously along the end of the first electrode layer 12.

It is to be noted that the phrase “each of the end regions is continuously provided along the end of the first electrode layer” in the present invention means that, for example, when the pattern shape of each of the first electrode layers is a shape with a plurality of sides such as a stripe, a rectangle, or a polygon, an end region is continuously provided at the edge of at least one of the sides of the first electrode layer.

On the other hand, when the pattern shape of each of the first electrode layers is a circular shape, an elliptical shape, or a shape with a continuously-curved edge, the above phrase means that an end region is continuously provided at the edge of the first electrode layer.

Further, the phrase “continuously provided” includes not only a case where an end region is continuously provided at the entire edge of at least one of the sides of the first electrode layer or at the entire edge of the first electrode layer but also a case where an end region is continuously provided at the edge of at least one of the sides of the first electrode layer except part thereof or at the edge of the first electrode layer except part thereof.

Further, the phrase “each of the end regions is discontinuously provided along the end of the first electrode layer” in the present invention means that end regions are provided at regular intervals along the end of the first electrode layer.

More specifically, the above phrase means that solid electrolyte layers are provided at regular intervals along the end of the first electrode layer. It is to be noted that, in this case, porous layers or catalyst layers, formed if necessary, may be provided at regular intervals along the end of the first electrode layer. Usually, the second electrode layer in each of the end regions is continuously provided.

FIGS. 4A and 4B are each a schematic plan view of one example of the first electrode base material used in the dye-sensitized solar cell module according to the present invention, which are intended to explain the end regions provided in the dye-sensitized solar cell module having such a structure as shown in FIG. 1A.

It is to be noted that the reference numerals shown in FIGS. 4A and 4B but not described here are the same as those described above with reference to FIG. 1A etc., and therefore a description thereof will not be repeated.

In the present invention, it is preferred that each of the end regions is continuously provided along the end of the first electrode layer. This makes it possible to continuously provide the solid electrolyte layers together with the second electrode layers provided along the ends of the first electrode layers, thereby more effectively preventing the occurrence of internal short-circuit in the dye-sensitized solar cells.

Here, in the present invention, the pattern shape of each of the first electrode layers is preferably a stripe. Therefore, the position of each of the end regions in planar view will be described below with reference to a case where the pattern shape of each of the first electrode layers is a stripe. It is to be noted that the pattern shape of each of the first electrode layers will be described later in detail in “II. Components of Dye-sensitized Solar Cell Module”.

When the pattern shape of each of the first electrode layers provided in the present invention is a stripe, the position of each of the end regions is not particularly limited as long as the end region is provided at the edge of at least one of the two short sides or two long sides of each of the stripes of the first electrode layers. However, the end region is preferably provided at the edge of at least one of the two long sides of each of the stripes of the first electrode layers.

Here, the dye-sensitized solar cell module according to the present invention has a shape such that it can have excellent bending workability when a base material having flexibility is used as the first base material. Further, when the first electrode layers are formed on the first base material in a stripe shape, the workability of the dye-sensitized solar cell module according to the present invention is significantly improved in a direction in which each of the stripes of the first electrode layers is aligned. Therefore, in the dye-sensitized solar cells, the distance between the first electrode layer and the second electrode layer easily changes at the edges of long sides of each of the stripes of the first electrode layers, and therefore there is a fear that internal short-circuit is likely to occur due to the contact between the first electrode layer and the second electrode layer.

Therefore, by providing the end region at the edge of at least one of the two long sides of each of the stripes of the first electrode layers, it is possible to more effectively prevent the occurrence of internal short-circuit in the dye-sensitized solar cells.

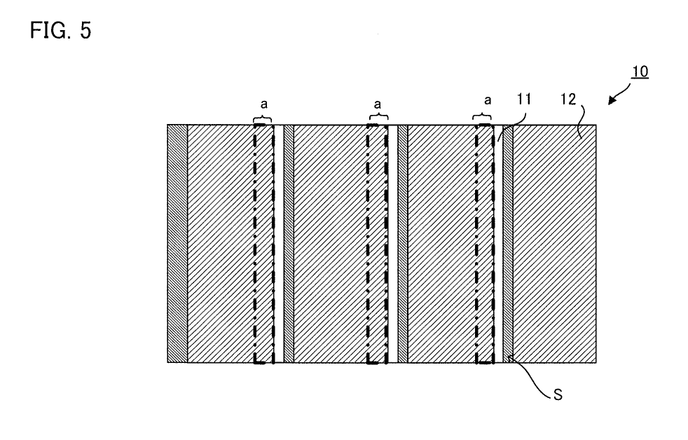

It is to be noted that when the end region is provided at the edge of at least one of the two long sides of each of the stripes of the first electrode layers, as shown in FIG. 4A, the end regions S may be provided at the edges of the two long sides of each of the stripes of the first electrode layers 12, or as shown in FIG. 5, the end region S may be provided at the edge of one of the two long sides of each of the stripes of the first electrode layers 12. It is to be noted that FIG. 5 is a schematic plan view of another example of the first electrode base material used in the dye-sensitized solar cell module according to the present invention. The first electrode base material shown in FIG. 5 is used in the dye-sensitized solar cell module having such a structure as shown in FIG. 2A.

Further, as shown in FIG. 4A, the end region S may be further provided along the edge of at least one of the two short sides of each of the stripes of the first electrode layers 12. Although not shown, it is not always necessary to provide the end region at the edge of at least one of the two short sides of each of the stripes of the first electrode layers.

Further, when the first electrode layers and the second electrode layers of the adjacent dye-sensitized solar cells are connected to each other inside the dye-sensitized solar cell module according to the present invention, as shown in FIGS. 4A and 4B and FIG. 5, each of the first electrode layers preferably has a pattern shape including the connection portion “a” at which the first electrode layer is connected to the second electrode layer.

In this case, as shown in FIG. 4A, the end region may be provided on the outside of the end of the first electrode layer 12 included in each of the connection portions “a”, or as shown in FIG. 4B and FIG. 5, the end region does not need to be provided on the outside of the end of the first electrode layer 12 included in each of the connection portions “a”.

In the present invention, it is particularly preferred that the end region is not provided on the outside of the end of the first electrode layer 12 included in each of the connection portions. This is because when the end region is provided on the outside of the end of the first electrode layer included in each of the connection portions, the solid electrolyte layer is provided between the first electrode layer and the second electrode layer, and therefore there is a possibility that contact failure is caused by the solid electrolyte layer.

3. End Regions

A method for adjusting each of the end regions in the present invention is not particularly limited as long as each of the end regions in the dye-sensitized solar cells can be adjusted to the above-described position in planar view and to the above-described position in sectional view. Usually, each of the end regions is adjusted by appropriately adjusting the pattern shape of each of the first electrode layers, the shape of each of the solid electrolyte layers, and the shape of each of the second electrode base materials each having the second electrode layer depending on factors such as the intended use and shape of the dye-sensitized solar cell module according to the present invention.

Further, each of the end regions in the present invention is not particularly limited as long as it does not include the first electrode layer but includes the first base material, the solid electrolyte layer, and the second electrode layer, and may further include another component. Examples of such another component include the porous layer and the catalyst layer formed if necessary.

II. Components of Dye-Sensitized Solar Cell Module

As described above, the dye-sensitized solar cell module according to the present invention comprises: a first electrode base material having one first base material and a plurality of first electrode layers formed in a pattern on the first base material; a plurality of second electrode base materials each having at least a second electrode layer; a plurality of porous layers provided either on the first electrode layers of the first electrode base material or on the second electrode layers of the second electrode base materials and containing a dye-sensitizer-supported fine particle of a metal oxide semiconductor; and a plurality of solid electrolyte layers provided between the porous layers and the first electrode layers of the first electrode base material or the second electrode layers of the second electrode base materials, on which the porous layers are not provided, and containing a redox couple, wherein a plurality of dye-sensitized solar cells each including the first electrode layer, the second electrode layer, the porous layer, and the solid electrolyte layer are connected to each other so that the first electrode layer of one of the adjacent dye-sensitized solar cells and the second electrode layer of the other of the adjacent dye-sensitized solar cells are electrically connected to each other.

Hereinbelow, each of the components of the dye-sensitized solar cell module according to the present invention will be described.

1. First Electrode Base Material

The first electrode base material in the present invention has one first base material and a plurality of first electrode layers formed in a pattern on the first base material.

The first electrode base material may be either a base material with transparency or a base material with no transparency, and is appropriately selected based on the light-receiving surface of the dye-sensitized solar cell module according to the present invention.

When the second electrode base materials are base materials with transparency, the first electrode base material may be either a base material with transparency or a base material with no transparency.

On the other hand, when the second electrode base materials are base materials with no transparency, the first electrode base material is a base material with transparency.

Each of them will be described below.

(1) Base Material with Transparency

When the first electrode base material is a base material with transparency, the first electrode base material usually has a transparent base material as the first base material and transparent electrode layers formed on the transparent base material as the first electrode layers.

(a) First Base Material

As described above, when the first electrode base material is a base material with transparency, a transparent base material is used as the first base material.

The transparent base material supports the transparent electrode layers (which will be described later).

The transparent base material is not particularly limited as long as the transparent electrode layers (which will be described later) can be formed thereon and it has self-supporting properties such that the dye-sensitized solar cells constituting the dye-sensitized solar cell module can be provided thereon. The transparent base material may have flexibility or no flexibility.

It is to be noted that, in the present invention, the “flexibility of the transparent base material” is not particularly limited as long as the transparent base material can be wound into a roll and can impart desired workability to the dye-sensitized solar cell module according to the present invention. More specifically, the “flexibility of the transparent base material” refers to the ability of the transparent base material to be bent when a force of 5 KN is exerted on the transparent base material according to a bending test method for fine ceramics specified in JIS R1601.

In the present invention, it is preferred that the transparent base material has flexibility. This is because the dye-sensitized solar cell module according to the present invention can have excellent workability.

Specific examples of such a transparent base material to be used include inorganic transparent base materials and resin base materials. Among them, resin base materials are preferred because they are lightweight and have excellent workability and cost reduction can be achieved.

Examples of the resin base materials include ethylene-tetrafluoroethylene copolymer films and base materials made of resins such as biaxially-oriented polyethylene terephthalate (PET), polyethersulfone (PES), polyether ether ketone (PEEK), polyether imide (PEI), polyimide (PI), polyester naphthalate (PEN), and polycarbonate (PC). Among them, base materials made of resins such as biaxially-oriented polyethylene terephthalate (PET), polyester naphthalate (PEN), and polycarbonate (PC) are preferably used in the present invention.

Examples of the inorganic transparent base materials include synthetic silica base materials and glass substrates.

The thickness of the transparent base material in the present invention can be appropriately selected depending on, for example, the intended use of the dye-sensitized solar cell module, but is usually preferably in the range of 5 μm to 2000 μm, particularly preferably in the range of 10 μm to 500 μm, and more preferably in the range of 25 μm to 200

The transparent base material used in the present invention preferably has excellent heat resistance, weather resistance, and gas barrier properties against water vapor and other gases. When the transparent base material has gas barrier properties, the dye-sensitized solar cells constituting the dye-sensitized solar cell module according to the present invention can have, for example, high temporal stability. Particularly, the transparent base material used in the present invention preferably has gas barrier properties such that an oxygen transmission rate under the conditions of a temperature of 23° C. and a humidity of 90% is 1 cc/m²/day·atm or less and a water vapor transmission rate under the conditions of a temperature of 37.8° C. and a humidity of 100% is 1 g/m²/day or less. In order to achieve such gas barrier properties, the transparent base material used in the present invention may have a gas barrier layer optionally provided thereon. It is to be noted that the above oxygen transmission rate is measured by an oxygen gas transmission rate measuring instrument (manufactured by MOCON Inc. under the trade name of OX-TRAN 2/20), and the above water vapor transmission rate is measured by a water vapor transmission rate measuring instrument (manufactured by MOCON Inc. under the trade name of PERMATRAN-W 3/31).

(b) First Electrode Layers

As described above, when the first electrode base material is a base material with transparency, transparent electrode layers are used as the first electrode layers.

The transparent electrode layers are formed in a pattern on the transparent base material described above.

The transparent electrode layers used in the present invention are not particularly limited as long as they have transparency and predetermined conductivity. Examples of a material used in such transparent electrode layers include metal oxides and conductive polymer materials.

Examples of the metal oxides include SnO₂, ZnO, a compound obtained by adding tin to indium oxide (ITO), and a compound obtained by adding zinc oxide to indium oxide (IZO). In the present invention, any of these metal oxides can be appropriately used, but fluorine-doped SnO₂ (hereinafter, referred to as “FTO”) and ITO are particularly preferably used. This is because FTO and ITO are excellent in both conductivity and sunlight transparency.

On the other hand, examples of the conductive polymer materials include polythiophene, polyaniline (PA), polypyrrole, polyethylenedioxythiophene (PEDOT), and derivatives thereof. These conductive polymer materials may be used in combination of two or more of them.

The total light transmittance of each of the transparent electrode layers in the present invention is preferably 85% or more, more preferably 90% or more, and particularly preferably 92% or more. When each of the transparent electrode layers has a total light transmittance within the above range, light can sufficiently pass through the transparent electrode layers and is therefore efficiently absorbed by the porous layers. It is to be noted that the above total light transmittance is measured in the visible light range with the use of an SM color computer (Type: SM-C) manufactured by Suga Test Instruments Co., Ltd.

The sheet resistance of each of the transparent electrode layers in the present invention is preferably 500Ω/□ or less, more preferably 300Ω/□ or less, and particularly preferably 50Ω/□ or less. If the sheet resistance exceeds the above upper limit, there is a possibility that generated charge cannot be adequately transmitted to an external circuit.

It is to be noted that the above sheet resistance is measured using a surface resistance meter (Loresta MCP™: 4-pin probe) manufactured by Mitsubishi Chemical Corporation in accordance with JIS R1637 (Test method for resistivity of conductive fine ceramic thin films with a four-point probe array).

Each of the transparent electrode layers in the present invention may have a single layer structure or a laminated structure having two or more layers. Examples of such a laminated structure include one having two or more layers made of materials different in work function from each other and one having two or more layers made of metal oxides different from each other.

The thickness of each of the transparent electrode layers in the present invention is not particularly limited as long as desired conductivity can be achieved depending on factors such as the intended use of the dye-sensitized solar cell module according to the present invention. However, the thickness of each of the transparent electrode layers in the present invention is usually preferably in the range of 5 nm to 2000 nm, and particularly preferably in the range of 10 nm to 1000 nm. If the thickness exceeds the above upper limit, there is a case where it is difficult to form uniform transparent electrode layers or it is difficult to achieve high photovoltaic conversion efficiency due to a reduction in total light transmittance. On the other hand, if the thickness is less than the above lower limit, there is a possibility that the transparent electrode layers are poor in conductivity.

It is to be noted that when each of the transparent electrode layers is constituted from two or more layers, the above thickness refers to the total thickness of all the layers.

The pattern shape of each of the transparent electrode layers is not particularly limited as long as a desired dye-sensitized solar cell module can be obtained, and is appropriately selected depending on factors such as the intended use and shape of the dye-sensitized solar cell module. However, the pattern shape of each of the transparent electrode layers is preferably a stripe because the transparent electrode layers can be easily formed in a pattern, and in addition, the second electrode base materials, the porous layers, and the solid electrolyte layers etc. formed to have a pattern corresponding to the pattern of the transparent electrode layers can also be easily formed.

When the first electrode layers and the second electrode layers of the adjacent dye-sensitized solar cells are electrically connected to each other inside the dye-sensitized solar cell module according to the present invention (hereinafter, sometimes referred to as “internal connection”), each of the transparent electrode layers preferably has a pattern shape including a connection portion for connection with the second electrode layer.

The connection portion is not particularly limited as long as internal connection between the first electrode layer and the second electrode layer of the adjacent dye-sensitized solar cells can be achieved. For example, when the pattern shape of each of the transparent electrode layers is a stripe, as shown in FIGS. 4A and 4B, the connection portion “a” is preferably a portion including the edge of short side of the stripe or, as shown in FIG. 5, the connection portion “a” is preferably a portion including the edge of long side of the stripe.

It is to be noted that also when each of the transparent electrode layers has a pattern shape other than a stripe, the connection portion is usually provided in a portion including the end of each of the first electrode layers formed in a pattern.

A method for forming the transparent electrode layers is not particularly limited as long as transparent electrode layers that can be used as the first electrode layers can be formed in a predetermined pattern on the above-described transparent base material. Examples of such a method include one in which transparent electrode layers are formed by vapor deposition, such as sputtering, using a metal mask, one in which a film of the above-described transparent electrode layer material is formed on the entire surface of the transparent base material and then etched in a predetermined pattern, and one in which a metal paste containing the above-described transparent electrode layer material is printed on the transparent base material.

Further, an auxiliary electrode may be laminated on each of the transparent electrode layers used in the present invention. The auxiliary electrode is a mesh electrode made of a conductive material. By using the auxiliary electrodes together with the transparent electrode layers, it is possible to enhance the power generation efficiency of the dye-sensitized solar cell module according to the present invention.

It is to be noted that the auxiliary electrode is the same as that used in common dye-sensitized solar cells, and is therefore not described here.

(2) Base Material with No Transparency

When the first electrode base material is a base material with no transparency, the first electrode base material is not particularly limited as long as it is such a base material with no transparency as described above in “(1) Base Material with transparency”, but usually has a first base material and metal layers formed in a pattern on the first base material.

(a) First Base Material

The first base material may be either a transparent base material or a first base material with no transparency. The transparent base material is the same as that described above in “(1) Base Material with Transparency”, and therefore a description thereof will not be repeated.

On the other hand, examples of the first base material with no transparency include resin base materials.

It is to be noted that resin materials used in the resin base materials are the same as those used in the above-described transparent resin base materials, and therefore a description thereof will not be repeated.

The specific thickness of the first base material with no transparency is the same as that of the transparent base material described above in “(1) Base Material with Transparency”, and therefore a description thereof will not be repeated.

(b) First Electrode Layers

When the first electrode base material is a base material with no transparency, as described above, metal layers are used as the first electrode layers.

The metal layers are not particularly limited as long as they can be formed in a predetermined pattern shape on the above-described first base material, but preferably have flexibility. This is because when the metal layers have flexibility, the dye-sensitized solar cell module according to the present invention can have higher workability.

Specific examples of a metal used in the metal layers include copper, aluminum, titanium, chromium, tungsten, molybdenum, platinum, tantalum, niobium, zirconium, zinc, various stainless steels, and alloys of two or more of them. Among them, titanium, chromium, tungsten, various stainless steels, and alloys of two or more of them are preferred.

The thickness of each of the metal layers is not particularly limited as long as the metal layers can function as the first electrode layers in the dye-sensitized solar cell module, but is usually preferably in the range of 5 μm to 1000 μm, more preferably in the range of 10 μm to 500 μm, and even more preferably in the range of 20 μm to 200 μm.

The pattern shape of each of the metal layers is the same as that of each of the transparent electrode layers described above, and therefore a description thereof will not be repeated.

A method for forming the metal layers is the same as a common method for forming metal layers. Examples of such a method include one in which a metal film is formed on the first base material by, for example, vapor deposition and then etched to form metal layers each having a predetermined pattern shape and one in which metal layers are formed in a pattern on the first base material by vapor deposition using a metal mask or the like.

(3) Other Components

The first electrode base material is not particularly limited as long as it has the first base material and the first electrode layers, but may have another component if necessary.

For example, when the porous layers (which will be described later) are provided on the second electrode base material (which will be described later) side, catalyst layers are preferably provided on the first electrode layers of the first electrode base material.

The catalyst layers function to contribute to improve power generation efficiency of the dye-sensitized solar cell module.

Examples of such catalyst layers include, but are not limited to, those formed by depositing Pt on the first electrode layers by vapor deposition and those formed using polyethylenedioxythiophene (PEDOT), polypyrrole (PP), polyaniline (PA), a derivative thereof, or a mixture of two or more of them.

The thickness of each of the catalyst layers is preferably in the range of 5 nm to 500 nm, more preferably in the range of 10 nm to 300 nm, and particularly preferably in the range of 15 nm to 100 nm.

A method for forming the catalyst layers is not particularly limited as long as catalyst layers can be formed on the above-described first electrode layers so as to have a desired thickness. Such a method is the same as a common method for forming a catalyst layer in a dye-sensitized solar cell, and is therefore not described here.

The catalyst layers are not particularly limited as long as they are formed on the first electrode layers that face the porous layers in the dye-sensitized solar cells. The catalyst layers may be formed on the entire surfaces of the first electrode layers or may be formed on part of the first electrode layers in a pattern. When formed in a pattern, the catalyst layers are preferably formed to have a shape corresponding to the pattern shape of each of the solid electrolyte layers (which will be described later). It is to be noted that the pattern shape of each of the solid electrolyte layers will be described later, and is therefore not described here.

(4) First Electrode Base Material

The first electrode base material in the present invention may be either the above-described base material with transparency or the above-described base material with no transparency, but is preferably the above-described base material with transparency.

Here, the porous layers (which will be described later) are provided either on the surfaces of the first electrode layers of the first electrode base material or on the surfaces of the second electrode layers of the second electrode base materials (which will be described later).

A method for forming the porous layers is preferably a method including a burning process. Therefore, metal base materials are preferably used as the second electrode layers and the porous layers are preferably formed on the metal base materials by burning.

For this reason, the base materials with no transparency are preferably used as the second electrode base materials, and therefore the base material with transparency is preferably used as the first electrode base material in the present invention.

2. Second Electrode Base Materials

The second electrode base materials in the present invention each have at least a second electrode layer.

The second electrode base materials may be either base materials with transparency or base materials with no transparency, and are appropriately selected based on the light-receiving surface of the dye-sensitized solar cell module according to the present invention.

When the above-described first electrode base material is a base material with transparency, the second electrode base materials may be either base materials with transparency or base materials with no transparency. On the other hand, when the above-described first electrode base material is a base material with no transparency, base materials with transparency are used as the second electrode base materials.

Such second electrode base materials are not particularly limited as long as they can function as electrodes, and may be each constituted from a second electrode layer or may each have a second electrode layer and a second base material for supporting the second electrode layer.

More specifically, when each of the second electrode base materials is constituted from a second electrode layer, single metal layers, that is, metal base materials are used as the second electrode base materials.

The metal base materials may have flexibility or no flexibility, but preferably have flexibility. This is because the dye-sensitized solar cell module according to the present invention can have excellent workability.

It is to be noted that the flexibility of the metal base material more specifically refers to the ability of the metal base material to be bent when a force of 5 KN is exerted on the metal base material according to a bending test method for metal materials specified in JIS Z 2248.

A metal used in the metal base materials is the same as that used in the above-described metal layers used in the first electrode base material, and therefore a description thereof will not be repeated.

The thickness of each of the metal base materials is the same as that of each of the above-described metal layers used in the first electrode base material.

On the other hand, when each of the second electrode base materials has a second electrode layer and a second base material, the above-described transparent electrode layer or metal layer can be used as the second electrode layer, and the above-described transparent base material or resin base material can be used as the second base material.

It is to be noted that, in each of the second electrode base materials, the second electrode layer is usually formed on the entire surface of the second base material.

The transparent base material, the resin base material, the transparent electrode layer, and the metal layer are the same as those used in the above-described first electrode base material, and therefore a description thereof will not be repeated.

If necessary, the second electrode base materials may have another component.

For example, when the porous layers (which will be described later) are formed on the first electrode layers of the first electrode base material, catalyst layers are preferably formed on the second electrode layers.

It is to be noted that the catalyst layers are the same as those described above in “1. First Electrode Base Material”, and therefore a description thereof will not be repeated.

It is preferred that the second electrode base materials in the present invention are each constituted from a second electrode layer, that is, the second electrode base materials are metal base materials. When the second electrode base materials are metal base materials, the porous layers can be formed on the second electrode layers of the second electrode base materials by burning.

The shape of each of the second electrode base materials is not particularly limited as long as the second electrode layers of the adjacent second electrode base materials do not come into contact with each other in the dye-sensitized solar cell module. Usually, each of the second electrode base materials has a shape such that the second electrode layers have a pattern corresponding to the pattern of the first electrode layers of the first electrode base material.

The phrase “the second electrode layers have a pattern corresponding to the pattern of the first electrode layers” in the present invention means that the second electrode layers have a pattern such that they can be provided so as to face the first electrode layers formed in a pattern, respectively, so that each of the dye-sensitized solar cells constituting the dye-sensitized solar cell module according to the present invention can have the second electrode layer.

More specifically, the above phrase means that the second electrode layers in the present invention have a pattern such that each of the second electrode layers can be continuously provided on each of the first electrode layers.

It is to be noted that when the pattern shape of each of the first electrode layers in the present invention is a stripe, the shape of each of the second electrode base materials is preferably a strip.

A method for forming the second electrode base materials is not particularly limited as long as second electrode base materials can be formed so that their second electrode layers have a pattern corresponding to the pattern of the first electrode layers of the first electrode base material. An example of an appropriate method for forming the second electrode base materials is one in which one second electrode base material substrate, from which a plurality of second electrode base materials used in the dye-sensitized solar cell module according to the present invention can be cut out, is cut into pieces having a desired shape.

When such a method is used, the solid electrolyte layers and/or the porous layers (which will be described later) having a pattern corresponding to the pattern of the first electrode layers of the first electrode base material can be easily formed by, for example, continuously forming a solid electrolyte layer and/or a porous layer on a second electrode layer of a second electrode base material substrate and then cutting the second electrode base material substrate.

3. Solid Electrolyte Layers

The solid electrolyte layers in the present invention are provided between the porous layers and the first electrode layers of the first electrode base material or the second electrode layers of the second electrode base materials, on which the porous layers are not provided, and contain a redox couple.

Here, the solid electrolyte layers contain a redox couple and have no fluidity, and are not particularly limited as long as they have a hardness such that they can be held between the first electrode layers and the second electrode layers without using sealing members or the like. The solid electrolyte layers include all-solid-state electrolyte layers using only solid materials and quasi-solid-state electrolyte layers (sometimes referred to as “gel electrolyte layers”) obtained by adding fine particles of an inorganic compound such as a metal oxide or a polymer compound such as rubber or a resin to a liquid material.

The solid electrolyte layers in the present invention usually have a pattern corresponding to the pattern of the first electrode layers of the first electrode base material.

It is to be noted that the phrase “the solid electrolyte layers have a pattern corresponding to the pattern of the first electrode layers of the first electrode base material” in the present invention means that the solid electrolyte layers have a pattern such that they can be formed on the first electrode layers formed in a pattern, respectively, so that each of the dye-sensitized solar cells constituting the dye-sensitized solar cell module according to the present invention can have the solid electrolyte layer.

More specifically, the above phrase means that the solid electrolyte layers in the present invention have a pattern such that each of the solid electrolyte layers can be continuously provided on each of the first electrode layers.

(1) Material of Solid Electrolyte Layers

The material of the solid electrolyte layers in the present invention contains a redox couple.

(a) Redox Couple

A redox couple used in the solid electrolyte layers in the present invention will be described.

The redox couple used in the solid electrolyte layers in the present invention is not particularly limited as long as it is one commonly used in electrolyte layers of dye-sensitized solar cells. Specific preferred examples of such a redox couple include a combination of iodine and an iodide and a combination of bromine and a bromide. Examples of the combination of iodine and an iodide include combinations of I₂ and a metal iodide such as LiI, NaI, KI, or CaI₂. Examples of the combination of bromine and a bromide include combinations of Br₂ and a metal bromide such as LiBr, NaBr, KBr, or CaBr₂.

The redox couple content of the solid electrolyte layers, that is, the ratio of the redox couple occupying the solid electrolyte layers is preferably in the range of 1 mass % to 50 mass %, and particularly preferably in the range of 5 mass % to 35 massa.

(b) Other Components

If necessary, the solid electrolyte layers used in the present invention may further contain another component in addition to the above-described redox couple.

Hereinbelow, such another component will be described.

(i) Polymer Compound

The solid electrolyte layers in the present invention preferably contain a polymer compound. This makes it possible to enhance the strength of the solid electrolyte layers. Hereinbelow, the polymer compound used in the solid electrolyte layers will be described.

Preferred examples of the polymer compound used in the solid electrolyte layers include a polymer compound having, in its main chain, polyether, polymethacrylic acid, polyacrylic acid alkyl ester, polymethacrylic acid alkyl ester, polycaprolactone, polyhexamethylene carbonate, polysiloxane, polyethylene oxide, polypropylene oxide, polyacrylonitrile, polyvinylidene fluoride, polyvinyl fluoride, polyhexafluoropropylene, polyfluoroethylene, polyethylene, polypropylene, polystyrene, or polyacrylonitrile and a copolymer of two or more of these monomer components.

Another example of the polymer compound used in the solid electrolyte layers is a cellulose-based resin. A cellulose-based resin has high heat resistance, and therefore an electrolyte layer solidified using a cellulose-based resin causes no liquid leakage even under high temperature and has high thermal stability. Specific examples of such a cellulose-based resin include: cellulose; cellulose acetates (CA) such as cellulose acetate, cellulose diacetate, and cellulose triacetate; cellulose esters such as cellulose acetate butyrate (CAB), cellulose acetate propionate (CAP), cellulose acetate phthalate, and cellulose nitrate; and cellulose ethers such as methyl cellulose, ethyl cellulose, benzyl cellulose, cyanoethyl cellulose, hydroxymethyl cellulose, hydroxyethyl cellulose, hydroxypropyl cellulose, hydroxypropylmethyl cellulose, and carboxymethyl cellulose. These cellulose-based resins may be used singly or in combination of two or more of them.

Among these cellulose-based resins, cationic cellulose derivatives are particularly preferably used from the viewpoint of compatibility with electrolyte solutions. A cationic cellulose derivative refers to one obtained by cationizing cellulose or its derivative by reacting its OH groups with a cationization agent. By allowing the solid electrolyte layers to contain such a cationic cellulose derivative, the solid electrolyte layers can achieve high electrolyte solution-holding performance and can have high thermal stability without causing no leakage of an electrolyte solution especially under high temperature or during application of pressure.

The molecular weight of such a cellulose-based resin varies depending on the type of cellulose-based resin and is not particularly limited. However, from the viewpoint of achieving excellent film-forming properties during formation of the electrolyte layers, the mass-average molecular weight of the cellulose-based resin is preferably 10,000 or more (in terms of polystyrene), and particularly preferably in the range of 100,000 to 200,000. For example, when ethyl cellulose is used as the cellulose-based resin, the ethyl cellulose preferably has a molecular weight such that a 2 mass % aqueous solution thereof has a viscosity in the range of 5 mPa·s to 1000 mPa·s, and especially in the range of 10 mPa·s to 500 mPa·s obtained by a viscometric measurement at 30° C.

The glass transition temperature of the cellulose-based resin is preferably in the range of 80° C. to 150° C. to allow the electrolyte layers to have adequate thermal stability.

The polymer compound used in the present invention preferably has transparency. When the polymer compound has transparency, the transparency of the solid electrolyte layers further increases. An increase in the transparency of the solid electrolyte layers makes it possible for the dye-sensitized solar cell module according to the present invention to have excellent appearance. In addition, it is also possible to prevent the solid electrolyte layers from blocking light when the solid electrolyte layers infiltrate the porous layers, thereby improving the performance of the dye-sensitized solar cell module according to the present invention.

The polymer compound content of the solid electrolyte layers is appropriately set in consideration of that if the polymer compound content is too low, the thermal stability of the solid electrolyte layers is reduced, and if the polymer compound content is too high, the photovoltaic conversion efficiency of the solar cells is reduced. More specifically, the amount of the polymer compound contained in the material of the solid electrolyte layers is preferably 5 mass % to 60 mass %. If the amount of the polymer compound contained in the material of the solid electrolyte layers is less than the above lower limit, there is a case where adequate adhesion to the porous layers (which will be described later) cannot be achieved or the mechanical strength of the solid electrolyte layers themselves is undesirably reduced. On the other hand, if the amount of the polymer compound contained in the material of the solid electrolyte layers exceeds the above upper limit, there is a fear that the function of transporting electric charge is undesirably inhibited due to the presence of a large amount of the polymer compound having insulation properties.

(ii) Other Components

The solid electrolyte layers in the present invention may further contain an optional component other than the above-described polymer compound. An example of such a component is an ionic liquid.

(2) Solid Electrolyte Layers

The thickness of each of the solid electrolyte layers in the present invention is preferably in the range of 10 nm to 100 μm, more preferably in the range of 1 μm to 50 μm, and particularly preferably in the range of 5 μm to 30 μm. When the thickness of each of the solid electrolyte layers is less than the above lower limit, there is a possibility that the solid electrolyte layers cannot adequately perform their function so that the power generation efficiency of the dye-sensitized solar cell module is reduced. On the other hand, if the thickness of each of the solid electrolyte layers exceeds the above upper limit, it is difficult to form the dye-sensitized solar cell module according to the present invention in the form of a thin film.

The shape of each of the solid electrolyte layers in the present invention is not particularly limited as long as the solid electrolyte layers can be provided on the first electrode layers and in the above-described end regions of the dye-sensitized solar cells in the present invention and the solid electrolyte layers can have a pattern corresponding to the above-mentioned pattern of the first electrode layers of the first electrode base material. Usually, the shape of each of the solid electrolyte layers is appropriately adjusted depending on the pattern shape of each of the first electrode layers.

Here, in the dye-sensitized solar cells, an area that contributes to power generation is preferably large to increase power generation efficiency. Therefore, each of the solid electrolyte layers in the present invention preferably has a shape such that its surface facing each of the first electrode layers can have a large area.

More specifically, when the pattern shape of each of the first electrode layers is a stripe, the solid electrolyte layers preferably have a shape such that the width of each of the solid electrolyte layers is larger than that of each of the first electrode layers. When the solid electrolyte layers have such a shape, their surfaces facing the first electrode layers can have an adequate area and the solid electrolyte layers can be provided in the end regions.

It is to be noted that the phrase “width of each of the first electrode layers” in the present invention refers to the distance from the end of the first electrode layer, on the outside of which the end region is provided, to the end of the first electrode layer opposite thereto, which is indicated by U in FIG. 10 and FIGS. 3A and 3B.

The phrase “width of each of the solid electrolyte layers” in the present invention refers to the distance from the end of the solid electrolyte layer located in the end region to the end of the solid electrolyte layer opposite thereto, which is indicated by V in FIG. 10 and FIGS. 3A and 3B.

In each of the end regions provided in the present invention, as described above, the solid electrolyte layer is preferably provided at the end of the second electrode layer. Therefore, the width of each of the solid electrolyte layers in the present invention is preferably the same as or larger than that of each of the second electrode layers.

It is to be noted that the phrase “width of each of the second electrode layers” in the present invention refers to the distance from the end of the second electrode layer located in the end region to the end of the second electrode layer opposite thereto, which is indicated by W in FIG. 1C and FIGS. 3A and 3B.

It is to be noted that when the first electrode layers or the second electrode layers used together with the solid electrolyte layers have a connection portion for internal connection between the first electrode layer and the second electrode layer of the adjacent dye-sensitized solar cells, the solid electrolyte layers usually have a shape such that they are not provided in the connection portions of the first electrode layers or of the second electrode layers.

Further, the solid electrolyte layers more preferably have a shape such that they are not provided on the outside of ends of the first electrode layers included in the connection portions, either. This is because there is a possibility that the solid electrolyte layers interfere with the connection between the first electrode layers and the second electrode layers due to their insulation function.

A method for forming the solid electrolyte layers in the present invention is not particularly limited as long as solid electrolyte layers can be formed so as to have a pattern corresponding to the pattern of the first electrode layers of the first electrode base material. An example of such a method is one in which the above-described material of the solid electrolyte layers is applied using a common coating method.

The solid electrolyte layers may be formed on the first electrode layer side of the first electrode base material or on the second electrode layer side of the second electrode base materials.

Here, when the solid electrolyte layers are formed in such a manner that they have the same width as the second electrode layers, as shown in FIG. 1C, the solid electrolyte layers 4 are preferably formed on the second electrode layers 22 of the second electrode base materials 20.

As described above, the second electrode base materials can be formed by cutting a second electrode base material substrate. Therefore, the solid electrolyte layers having the same width as the second electrode layers can be easily formed by continuously forming a solid electrolyte layer on a second electrode base material substrate in advance and then cutting the second electrode base material substrate.

On the other hand, when the solid electrolyte layers are formed in such a manner that they are larger in width than the second electrode layers, as shown in FIG. 3B, the solid electrolyte layers 4 are usually formed in a pattern on the first electrode layers 12 of the first electrode base material 10.

When the porous layers are formed on the electrode layers, on the side of which the solid electrolyte layers are formed, the solid electrolyte layers are usually formed on the entire surfaces of the porous layers.

4. Porous Layers

The porous layers in the present invention are formed on the surfaces of either the first electrode layers of the first electrode base material or on the surfaces of the second electrode layers of the second electrode base materials, and contain dye-sensitizer-supported fine particles of a metal oxide semiconductor.

Further, the porous layers in the present invention usually have a pattern corresponding to the pattern of the first electrode layers of the first electrode base material.

It is to be noted that the phrase “the porous layers in the present invention have a pattern corresponding to the pattern of the first electrode layers of the first electrode base material” means that the porous layers have a pattern such that they can be formed on the surfaces of the first electrode layers formed in a pattern, respectively, so that each of the dye-sensitized solar cells constituting the dye-sensitized solar cell module according to the present invention can have the porous layer.

More specifically, the porous layers in the present invention have a pattern such that each of the porous layers can be continuously formed on each of the first electrode layers.

Hereinbelow, metal oxide semiconductor fine particles and a dye sensitizer used in the porous layers will be described.

(a) Metal Oxide Semiconductor Fine Particles

The metal oxide semiconductor fine particles are not particularly limited as long as they are made of a metal oxide having semiconductor characteristics. Examples of such a metal oxide constituting the metal oxide semiconductor fine particles include TiO₂, ZnO, SnO₂, ITO, ZrO₂, MgO, Al₂O₃, CeO₂, Bi₂O₃, Nn₃O₄, Y₂O₃, WO₃, Ta₂O₅, Nb₂O₅, and La₂O₃.

Among them, metal oxide semiconductor fine particles made of TiO₂ are most preferably used in the present invention. This is because TiO₂ has particularly excellent semiconductor characteristics.

The average particle size of the metal oxide semiconductor fine particles is usually preferably in the range of 1 nm to 10 μm, and particularly preferably in the range of 10 nm to 1000 nm.

It is to be noted that the average particle size of the metal oxide semiconductor fine particles refers to an average primary particle size.

(b) Dye Sensitizer

The dye sensitizer is not particularly limited as long as it can absorb light to generate electromotive force. Examples of such a dye sensitizer include organic dyes and metal complex dyes. Examples of the organic dyes include acridine-based dyes, azo-based dyes, indigo-based dyes, quinone-based dyes, coumarin-based dyes, merocyanine-based dyes, phenylxanthene-based dyes, indoline-based dyes, and carbazole-based dyes. Among these organic dyes, coumarin-based dyes are preferably used in the present invention. Preferred examples of the metal complex dyes include ruthenium-based dyes. Among the ruthenium-based dyes, ruthenium bipyridine dyes and ruthenium terpyridine dyes as ruthenium complexes are particularly preferably used. This is because such ruthenium complexes have a wide light absorption wavelength range, and therefore the wavelength range of light that can be converted into electricity can be significantly broadened.

(c) Optional Components

The porous layers may contain an optional component other than the metal oxide semiconductor fine particles. Examples of such an optional component include resins. By adding a resin to the porous layers used in the present invention, it is possible to improve the brittleness of the porous layers.

Examples of the resins that can be used in the porous layers in the present invention include polyvinyl pyrrolidone, ethyl cellulose, and caprolactam.

(d) Porous Layers

The thickness of each of the porous layers in the present invention is not particularly limited and can be appropriately determined depending on the intended use of the dye-sensitized solar cell module according to the present invention. However, the thickness of each of the porous layers in the present invention is usually preferably in the range of 1 μm to 100 μm, and particularly preferably in the range of 3 μm to 30 μm.

The porous layers in the present invention are formed either on the first electrode layers of the first electrode base material or on the second electrode layers of the second electrode base materials.

The shape of each of the porous layers and the positions where the porous layers are formed are the same as the shape of each of the solid electrolyte layers and the positions where the solid electrolyte layers are formed, which have been described above in “3. Solid Electrolyte Layers”, and therefore a description thereof will not be repeated.

(2) Method for Forming Porous Layers

A method for forming the porous layers in the present invention is not particularly limited as long as porous layers can be formed on the first electrode layers of the first electrode base material or on the second electrode layers of the second electrode base materials so as to have a desired thickness.

In the present invention, the porous layers are preferably formed on the second electrode layers of the second electrode base materials. In this case, porous layers having a desired shape can be formed by continuously forming a porous layer on a second electrode base material substrate and then cutting the second electrode base material substrate. Therefore, the porous layers can be formed more simply as compared to a case where the porous layers are formed in a pattern on the first electrode layers of the first electrode base material.

A specific example of the method for forming the porous layers is as follows.

First, a coating liquid for forming porous layer containing at least the above-described metal oxide semiconductor fine particles, a binder resin, and a solvent is prepared. Then, the coating liquid for forming porous layer is applied onto metal layers used as the second electrode layers to a desired thickness to form coated films for forming porous layers. Then, the coated films for forming porous layers are burned to thermally decompose the binder resin to form layers for forming porous layers. Then, the above-described dye sensitizer is adhered to the surfaces of the layers for forming porous layers to form porous layers.

It is to be noted that the binder resin and the solvent used in the coating liquid for forming porous layer are the same as those used in common method for forming a porous layer, and are therefore not described here. If necessary, the coating liquid for forming porous layer may contain, in addition to the above-mentioned components, a dispersing agent.

A method for applying the coating liquid for forming porous layer and burning conditions are the same as those employed in a common method for forming a porous layer, and are therefore not described here.

Alternatively, the following method may be used for forming the porous layers.

First, a composition for forming porous layer containing the above-described metal oxide semiconductor fine particles and a solvent is applied onto the second electrode layers and dried to form layers for forming porous layers. Then, a dye sensitizer is adhered to the layers for forming porous layers to form porous layers. The solvent used in the composition for forming porous layer, a method for applying the composition for forming porous layer, and drying conditions are the same as those employed in a common method for forming a porous layer, and are therefore not described here.

It is to be noted that this method can be used also when the porous layers are formed on the first electrode layers of the first electrode base material.

Alternatively, the following method may be used for forming the porous layers.

A release layer is formed on a heat-resistant substrate and porous layers are formed on the release layer by the same method as the above-described method in which porous layers are formed on the second electrode layers by burning. Then, the porous layers are bonded to the second electrode layers, and the heat-resistant substrate is removed.

It is to be noted that this method can be used also when the porous layers are formed on the first electrode layers of the first electrode base material.

5. Dye-Sensitized Solar Cells

The dye-sensitized solar cells in the present invention each include the above-described first electrode layer, second electrode layer, porous layer, and solid electrolyte layer. Further, the dye-sensitized solar cells have the above-described end region.

The dye-sensitized solar cells in the present invention are not particularly limited as long as they include the above-described components and have the above-described end region. However, the dye-sensitized solar cells preferably have a layer structure in which the first electrode layer, the solid electrolyte layer, the porous layer, and the second electrode layer are laminated in this order. By allowing the dye-sensitized solar cells to have such a layer structure, it is possible to enhance the productivity of the dye-sensitized solar cell module according to the present invention.

6. Dye-Sensitized Solar Cell Module

The dye-sensitized solar cell module according to the present invention is constituted from the above-described dye-sensitized solar cells, and the first electrode layer of one of the adjacent dye-sensitized solar cells and the second electrode layer of the other of the adjacent dye-sensitized solar cells are electrically connected to each other.

The dye-sensitized solar cell module according to the present invention is not particularly limited as long as at least one of the dye-sensitized solar cells has the above-described end region, but usually, the dye-sensitized solar cells constituting the dye-sensitized solar cell module have the above-described end region.

As described above, in the dye-sensitized solar cell module according to the present invention, the first electrode layer of one of the adjacent dye-sensitized solar cells and the second electrode layer of the other of the adjacent dye-sensitized solar cells are electrically connected to each other.

A method for connecting the first electrode layers and the second electrode layers to each other is not particularly limited as long as the first electrode layers and the second electrode layers of the adjacent dye-sensitized solar cells in the dye-sensitized solar cell module can be electrically connected to each other. For example, the first electrode layers and the second electrode layers of the adjacent dye-sensitized solar cells may be internally connected to each other by, for example, bringing the first electrode layers and the second electrode layers into direct contact with each other or by forming conductive layers between the first electrode layers and the second electrode layers. Alternatively, the first electrode layers and the second electrode layers of the adjacent dye-sensitized solar cells may be electrically externally connected to each other by using electric conductors or the like.

In the present invention, it is preferred that the first electrode layers and the second electrode layers of the adjacent dye-sensitized solar cells are internally connected to each other. This is because such a connection method is easier than a method in which the first electrode layers and the second electrode layers of the adjacent dye-sensitized solar cells are electrically connected to each other outside the dye-sensitized solar cell module.

In the present invention, it is more preferred that the first electrode layers and the second electrode layers of the adjacent dye-sensitized solar cells are connected to each other through conductive layers formed between them. This makes it possible to more appropriately prevent poor connection in the dye-sensitized solar cell module according to the present invention.

It is to be noted that examples of a material used for forming the conductive layer include common conductive adhesives.

The dye-sensitized solar cell module according to the present invention may be a single dye-sensitized solar cell module obtained by connecting the above-described dye-sensitized solar cells to each other or a large-sized dye-sensitized solar cell module obtained by connecting the above-described dye-sensitized solar cell modules to each other.

7. Other Components

The dye-sensitized solar cell module according to the present invention is not particularly limited as long as it comprises the above-described components, and if necessary, may further comprise an appropriately-selected component. An example of such a component is a transparent resin film or a metal laminate film provided on the first electrode base material and the second electrode base materials of the dye-sensitized solar cell module to be used as a packaging film for the dye-sensitized solar cell module.

III. Method for Producing Dye-Sensitized Solar Cell Module

A method for producing the dye-sensitized solar cell module according to the present invention is not particularly limited as long as the above-described dye-sensitized solar cell module can be produced. For example, the following production method can be appropriately used.

A method for producing a dye-sensitized solar cell module appropriately used in the present invention comprises steps of: a first electrode base material-forming step in which a plurality of first electrode layers are formed on a first base material to obtain a first electrode base material; a second electrode base material substrate preparation step in which one second electrode base material substrate having a second electrode layer, from which a plurality of second electrode base materials can be cut out, is prepared; a porous layer-forming step in which porous layers are formed either on the surfaces of the first electrode layers or on the surfaces of the second electrode layers; a solid electrolyte layer-forming step in which either a step of forming solid electrolyte layers in a pattern corresponding to the pattern of the first electrode layers on the first electrode layer side of the first electrode base material or a step of continuously forming a solid electrolyte layer on the second electrode layer side of the second electrode base material substrate is performed; a cutting step in which a plurality of second electrode base materials are formed by cutting the second electrode base material substrate; a bonding step in which the first electrode base material and the second electrode base materials are bonded together by allowing the first electrode layer side of the first electrode base material and the second electrode layer side of the second electrode base materials to face each other and bringing them into close contact with each other with the solid electrolyte layers being interposed between them; and a connection step in which the first electrode layer of one of adjacent dye-sensitized solar cells and the second electrode layer of the other of the adjacent dye-sensitized solar cells are electrically connected to each other.

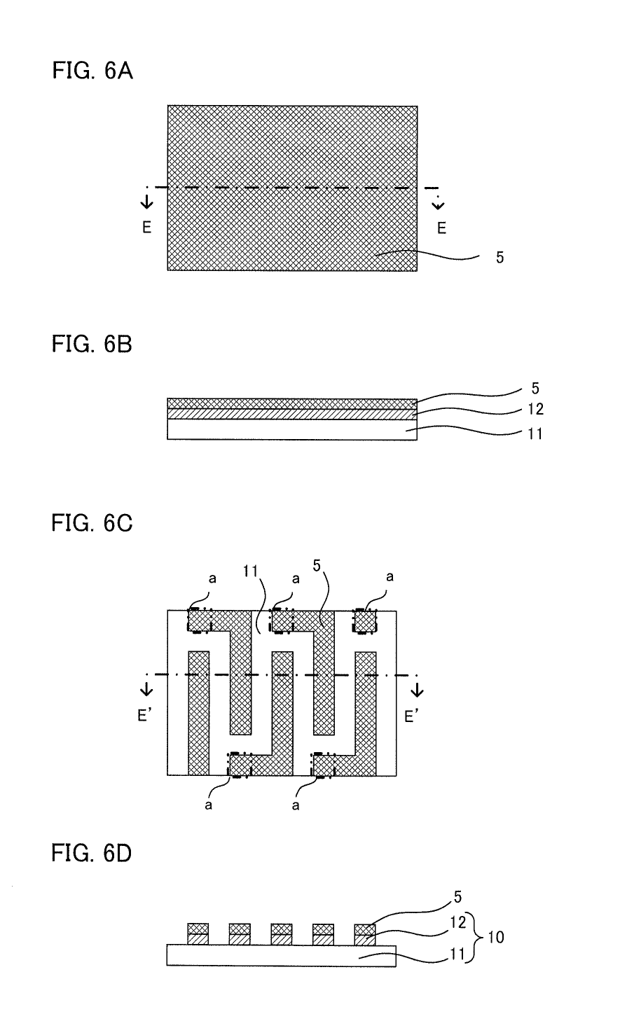

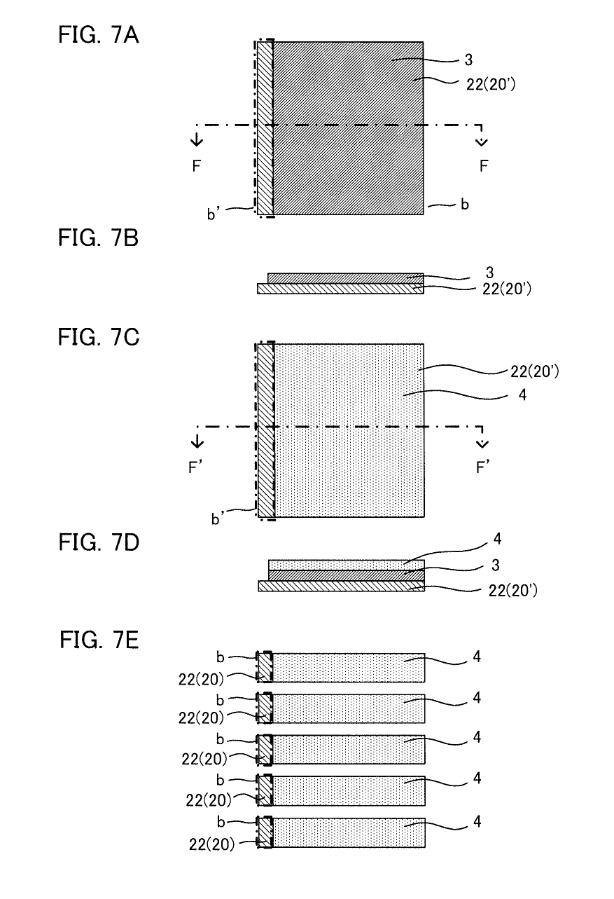

Here, the method for producing a dye-sensitized solar cell module will be described with reference to drawings. FIGS. 6A to 6D and FIGS. 7A and 7D are step diagrams of one example of a method for producing the dye-sensitized solar cell module according to the present invention, more specifically, step diagrams of a method for producing the dye-sensitized solar cell module shown in FIGS. 1A to 1C.

First, the first electrode base material-forming step will be described. As shown in FIGS. 6A and 6B, in the first electrode base material-forming step, a first electrode layer 12 is continuously formed on a first base material 11. In the first electrode base material-forming step, a catalyst layer 5 may be further formed. In this case, the catalyst layer 5 is continuously formed so as to be laminated on the first electrode layer 12. It is to be noted that FIG. 6A is a top view of one example of the first base material 11 on which the first electrode layer 12 and the catalyst layer 5 are continuously formed and FIG. 6B is a sectional view taken along the line E-E in FIG. 6A.

Then, as shown in FIGS. 6C and 6D, the first electrode layer 12 and the catalyst layer 5 are patterned in a predetermined pattern by etching or the like to obtain a first electrode base material 10 having the single first base material 11 and the first electrode layers 12 and the catalyst layers 5 formed in a pattern on the first base material 11. FIG. 6C shows one example of the first electrode base material 10 in which the first electrode layers 12 and the catalyst layers 5 are formed in a stripe shape and each of the first electrode layers 12 and the catalyst layers 5 has a connection portion “a” including the edge of short side of its stripe.

It is to be noted that FIG. 6C is a top view of one example of the first electrode base material 10 formed in the first electrode base material-forming step and FIG. 6D is a sectional view taken along the line E′-E′ in FIG. 6C.

Although not shown, in the first electrode base material-forming step, first electrode layers may be directly formed in a pattern on a first base material by, for example, vapor deposition using a metal mask or the like.

Then, the second electrode base material substrate preparation step and the porous layer-forming step will be described. As shown in FIGS. 7A and 7B, in the second electrode base material substrate preparation step, a second electrode base material substrate 20′ having a second electrode layer 22 is prepared. Then, in the porous layer-forming step, a porous layer 3 is continuously formed on the second electrode layer 22. It is to be noted that when first electrode layers and second electrode layers of adjacent dye-sensitized solar cells are internally connected to each other in the connection step (which will be described later), the porous layer 3 is preferably continuously formed on the second electrode layer 22 in a portion other than a portion “b′” to be used as connection portions “b” (see FIG. 7E) of the second electrode layers 22 of second electrode base materials 20 cut out from the second electrode base material substrate 20′.

It is to be noted that FIG. 7A is a top view of one example of the second electrode base material substrate on which the porous layer 3 is formed in the porous layer-forming step and FIG. 7B is a sectional view taken along the line F-F in FIG. 7A.

Although not shown, in the porous layer-forming step, porous layers may be formed on the first electrode layers.

Then, the solid electrolyte layer-forming step will be described.

As shown in FIGS. 7C and 7D, in the solid electrolyte layer-forming step, a solid electrolyte layer 4 containing a redox couple is continuously formed on the porous layer 3 formed on the second electrode base material substrate 20′.

It is to be noted that FIG. 7C is a top view of one example of the second electrode base material substrate 20′ on which the solid electrolyte layer 4 is formed and FIG. 7D is a sectional view taken along the line F′-F′ in FIG. 7C.

Although not shown, in the solid electrolyte layer-forming step, solid electrolyte layers may be formed in a pattern corresponding to the pattern of the first electrode layers on the first electrode layers of the first electrode base material.

Then, the cutting step will be described.

As shown in FIG. 7E, in the cutting step, second electrode base materials 20 are formed by cutting the second electrode base material substrate 20′ into pieces having a desired shape. FIG. 7E shows a case where the second electrode base materials 20 are formed into a shape such that the adjacent second electrode base materials 20 do not come into contact with each other in a resultant dye-sensitized solar cell module and the width of the solid electrolyte layer 4 formed on each of the second electrode base materials 20 is larger than that of each of the first electrode layers shown in FIG. 6C.

Then, the bonding step and the connection step will be described.

In the bonding step, the catalyst layers 5 formed on the first electrode layers 12 of the first electrode base material 10 shown in FIG. 6D and the porous layers 3 formed on the second electrode layers 22 of the second electrode base materials 20 shown in FIG. 7E are allowed to face each other and are then brought into close contact with each other with the solid electrolyte layers 4 being interposed between the catalyst layers 5 and the porous layers 3. In this way, a dye-sensitized solar cell module 100 having a structure shown in FIGS. 1A to 1C can be obtained in this step.

Further, in the connection step, as shown in FIG. 1A, the first electrode layers 11 and the second electrode layers 22 of adjacent dye-sensitized solar cells 1 can be electrically connected to each other by, for example, bringing the connection portions “a” each including the edge of short side of each of the stripes of the first electrode layers 12 into direct contact with the connection portions “b” each including the edge of short side of strip of each of the second electrode layers 22 when the catalyst layers 5 formed on the first electrode layers 12 of the first electrode base material 10 shown in FIG. 6D and the porous layers 3 formed on the second electrode layers 22 of the second electrode base materials 20 shown in FIG. 7E are allowed to face each other and are then bonded together with the solid electrolyte layers 4 being interposed between the catalyst layers 5 and the porous layers 3.

It is to be noted that as described above, when the first electrode layers and the second electrode layers of the adjacent dye-sensitized solar cells are connected to each other inside the dye-sensitized solar cell module, the bonding step and the connection step mentioned above can be performed at the same time.

Hereinbelow, each of the steps will be described.

1. First Electrode Base Material-Forming Step

The first electrode base material-forming step is a step in which a plurality of first electrode layers are formed on a first base material to obtain a first electrode base material.

The form of a first base material used in this step is not particularly limited as long as a desired dye-sensitized solar cell module can be obtained, but the first base material is preferably a flexible long base material wound into a roll. By using such a base material as the first base material, it is possible to perform this step by Roll to Roll process (hereinafter, simply referred to as “R to R process”) and to form porous layers and/or solid electrolyte layers on the first electrode base material side by R to R process in the porous layer-forming step and/or the solid electrolyte layer-forming step (which will be described later). This makes it possible to achieve high production efficiency.

A first base material used in this step, a material for forming first electrode layers, a method for forming first electrode layers, and a first electrode base material formed in this step are the same as those described above in “II. Components of Dye-Sensitized Solar Cell Module”, and therefore a description thereof will not be repeated.

2. Second Electrode Base Material Substrate Preparation Step

The second electrode base material substrate preparation step is a step in which one second electrode base material substrate, from which a plurality of second electrode base materials can be cut out, is prepared.

The form of a second electrode base material substrate prepared in this step is not particularly limited as long as a desired dye-sensitized solar cell module can be obtained, but the second electrode base material substrate is preferably a flexible long base material wound into a roll. By preparing such a base material as the second electrode base material substrate, it is possible to form a porous layer and/or a solid electrolyte layer on the second electrode base material side by R to R process in the porous layer-forming step and/or the solid electrolyte layer-forming step (which will be described later). This makes it possible to achieve high production efficiency.

More specifically, the second electrode base material substrate prepared in this step is not particularly limited as long as the second electrode base materials described above in “II. Components of Dye-Sensitized Solar Cell Module” can be cut out from it. The material, thickness, etc. of the second electrode base material substrate are the same as those described above in “2. Second Electrode Base Material”, and therefore a description thereof will not be repeated.

3. Porous Layer-Forming Step

The porous layer-forming step is a step in which porous layers are formed either on the surfaces of the first electrode layers or on the surfaces of the second electrode layers.

A material used in this step for forming a porous layer (s), a method for forming a porous layer(s), and a porous layer(s) formed in this step are the same as those described above in “3. Porous Layers” in “II. Components of Dye-Sensitized Solar Cell Module”, and therefore a description thereof will not be repeated.

It is to be noted that in this step, a porous layer(s) is (are) preferably formed by R to R process. This makes it possible to produce the dye-sensitized solar cell module according to the present invention with high productivity.

4. Solid Electrolyte Layer-Forming Step

The solid electrolyte layer-forming step is a step in which either the step of forming solid electrolyte layers on the first electrode layer side of the first electrode base material in a pattern corresponding to the pattern of the first electrode layers or the step of continuously forming a solid electrolyte layer on the second electrode layer side of the second electrode base material substrate is performed.

It is to be noted that a material used in this step for forming a solid electrolyte layer(s) is not particularly limited as long as desired solid electrolyte layers can be formed and the first electrode base material and the second electrode base materials can be bonded together with the solid electrolyte layers being interposed between them in the bonding step (which will be described later). However, the material used in this step preferably contains a redox couple and a polymer compound.

A material used in this step for forming a solid electrolyte layer(s), a method for forming a solid electrolyte layer(s), and a solid electrolyte layer(s) formed in this step are the same as those described above in “4. Solid Electrolyte Layers” in “II. Components of Dye-Sensitized Solar Cell Module”, and therefore a description thereof will not be repeated.

It is to be noted that in this step, a solid electrolyte layer(s) is (are) preferably formed by R to R process. This makes it possible to produce the dye-sensitized solar cell module according to the present invention with high productivity.

5. Cutting Step

The cutting step is a step in which a plurality of second electrode base materials are formed by cutting the second electrode base material substrate.

The shape of each of the second electrode base materials formed in this step is not particularly limited as long as the adjacent second electrode base materials do not come into contact with each other in the dye-sensitized solar cell module according to the present invention and the second electrode layers can have a pattern corresponding to the pattern of the first electrode layers of the first electrode base material, and is appropriately selected depending on factors such as the intended use of the dye-sensitized solar cell module according to the present invention.

When the above-described porous layer and/or solid electrolyte layer is/are formed on the second electrode base material substrate, the second electrode base material substrate is usually cut in such a manner that porous layers and/or solid electrolyte layers provided on second electrode base materials formed in this step have a pattern corresponding to the pattern of the first electrode layers.

A method used in this step for cutting the second electrode base material substrate is not particularly limited as long as second electrode base materials having a desired shape can be cut out from the second electrode base material substrate, and a well-known method can be used.

6. Bonding Step

The bonding step is a step in which the first electrode base material and the second electrode base materials are bonded together by allowing the first electrode layer side of the first electrode base material and the second electrode layer side of the second electrode base materials to face each other and bringing them into close contact with each other with the solid electrolyte layers being interposed between them.

In this step, the first electrode base material and the second electrode base materials are bonded together in such a manner that the above-described end regions are provided outside the ends of the first electrode layers.

It is to be noted that, in this step, when the porous layers are provided on the first electrode layers of the first electrode base material, the porous layers and the second electrode layers are allowed to face each other and are brought into close contact with each other with the solid electrolyte layers being interposed between them. On the other hand, when the porous layers are provided on the second electrode layers of the second electrode base materials, the first electrode layers and the porous layers are allowed to face each other and are brought into close contact with each other with the solid electrolyte layers being interposed between them.

Further, when catalyst layers are provided on the electrode layers on which the porous layers are not provided, the porous layers and the catalyst layers are allowed to face each other and are brought into close contact with each other with the solid electrolyte layers being interposed between them.

A method used in this step for bonding together the first electrode base material and the second electrode base materials is not particularly limited as long as the first electrode layers and the porous layers can be adequately brought into close contact with each other with the solid electrolyte layers being interposed between them. However, a roll lamination method or a vacuum lamination method is preferably used because the first electrode base material and the second electrode base materials can be easily bonded together without trapping air between their surfaces in close contact with each other.

7. Connection Step

The connection step is a step in which the first electrode layer of one of the adjacent dye-sensitized solar cells and the second electrode layer of the other of the adjacent dye-sensitized solar cells are electrically connected to each other.

A method used in this step for connecting the first electrode layers and the second electrode layers to each other is the same as that described above in “II. Components of Dye-Sensitized Solar Cell Module”, and therefore a description thereof will not be repeated.

8. Other Steps

The above-described method for producing the dye-sensitized solar cell module according to the present invention is not particularly limited as long as it comprises the above-described steps, and if necessary, may further comprise an appropriately-selected step.

An example of such a step is one in which a dye-sensitized solar cell module produced through the above steps is packaged in transparent resin films or metal laminate films provided on the first electrode base material and the second electrode base materials thereof.

Another example is a step in which a large-sized dye-sensitized solar cell module is produced by assembling a plurality of dye-sensitized solar cell modules produced by repeating the above steps.

It is to be noted that the present invention is not limited to the above embodiments. The above embodiments are merely examples, and embodiments having substantially the same structure as the technical idea described in the claims of the present invention and providing the same functions and effects are all included in the technical scope of the present invention.

### EXAMPLES

Hereinbelow, the present invention will be described more specifically with reference to the following example.

### Example 1

<Preparation of First Electrode Base Material>

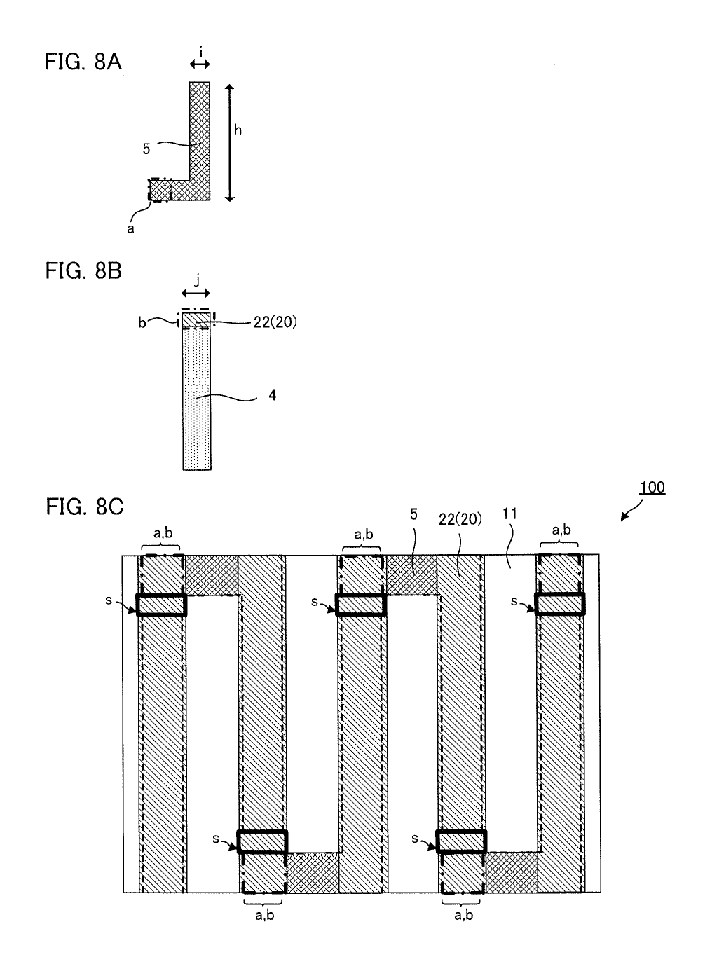

A transparent conductive film obtained by forming an ITO film (first electrode layer) on a PEN film (first base material) was prepared. Then, a catalyst layer was formed on the ITO film by depositing platinum with a thickness of 13 Å (transmittance: 72%). The transparent conductive film having the catalyst layer formed thereon was subjected to patterning by forming insulating portions by laser scribing in a laminate of the ITO film and the catalyst layer so that, as shown in FIG. 6C, a plurality of first electrode layers each having a stripe shape and a connection portion “a” including the edge of short side of the stripe were formed. The interval between the insulating portions in a longitudinal direction (i.e., a portion indicated by “h” in FIG. 8A) was 100 mm and the interval between the insulating portions in the short-side direction (i.e., a portion indicated by “i” in FIG. 8A) was 12 mm.

In this way, a first electrode base material (counter electrode base material) was obtained.

It is to be noted that FIG. 8A is a schematic diagram for explaining the shape of each of the first electrode layers formed in Example 1.

<Preparation of Ink for Forming Porous Layer>

Charged into 16.7 g of ethanol were 5 g of porous titanium oxide fine particles (manufactured by Nippon Aerosil Co., Ltd. under the trade name of P25), and then 0.25 g of acetylacetone and 20 g of zirconia beads (φ1.0 mm) were added thereto to obtain a mixed liquid. The mixed liquid was stirred by a paint shaker, and 0.25 g of polyvinyl pyrrolidone (manufactured by Nippon Shokubai Co., Ltd. under the trade name of K-30) was further added thereto as a binder to prepare an ink for forming porous layer.

<Formation of Porous Layer>

The thus prepared ink for forming porous layer was applied by a doctor blade method onto a titanium foil as a second electrode base material substrate in an area with a width of 10 cm to form a layer for forming porous layer. As shown in FIGS. 7A and 7B, an uncoated portion where only the titanium foil was present without being coated with the ink for forming porous layer was provided outside the layer for forming porous layer (i.e., the connection portion “b′” of the second electrode base material substrate 20′).

Then, the titanium foil having the layer for forming porous layer was dried at 120° C. so that a 9 μm-thick layer containing numbers of titanium oxide fine particles was formed. The layer containing titanium oxide fine particles was pressed at 0.1 t/cm² by a press machine. After the pressing, the layer was burned at 500° C. for 30 minutes.

Then, an application liquid for allowing a porous layer to support a dye (hereinafter, simply referred to as an “application liquid”) was prepared by dissolving an organic dye as a dye sensitizer (manufactured by Mitsubishi Paper Mills Limited under the trade name of D358) in a 1:1 (by volume) solution of acetonitrile and tert-butyl alcohol to achieve a concentration of 3.0×10⁻⁴ mol/L. The layer containing titanium oxide fine particles formed on the second electrode base material substrate was immersed in the application liquid for 3 hours, and was then taken out of the application liquid. The application liquid adhered to the titanium oxide fine particles was washed with acetonitrile and air-dried. In this way, a porous layer containing titanium oxide fine particles supporting a sensitizing dye on their pore surfaces was formed.

<Preparation of Application Liquid for Forming Solid Electrolyte Layer>

Added to and dissolved in a solution was 0.043 g of potassium iodide, obtained by dissolving 0.14 g of cationic hydroxycellulose (manufactured by Daicel Corporation under the trade name of JELLNER QH200) in 2.72 g of ethanol, by stirring to obtain a solution. Then, 0.18 g of 1-ethyl-3-methylimidazolium tetracyanoborate (EMIm-B(CN)4), 0.5 g of 1-propyl-3-methylimidazolium iodide (PMIm-I), and 0.025 g of I₂ were added to and dissolved in the solution by stirring. In this way, a coatable application liquid for forming solid electrolyte layer was prepared.

<Formation of Solid Electrolyte Layer>

The application liquid for forming solid electrolyte layer was applied onto the above-mentioned porous layer (10 cm in width) by a doctor blade method and dried at 100° C. to form a solid electrolyte layer.

<Cutting of Second Electrode Base Material Substrate>

As shown in FIG. 7E, the substrate with electrolyte layer was cut into strip-shaped pieces each having a connection portion “b” including the edge of short side of strip of each second electrode layer 22. It is to be noted that the width of each of the strips (i.e., a width indicated by “j” in FIG. 8B) was 10 mm.

In this way, second electrode base materials (conductive base materials) were obtained.

It is to be noted that FIG. 8B is a schematic diagram for explaining the shape of each of the second electrode base materials formed in Example 1.

<Production of Dye-Sensitized Solar Cell Module>

As shown in FIG. 8C, a conductive adhesive was placed on the connection portions “b” of the second electrode base materials 20 cut to have a strip shape. Then the first electrode base material 10 and the second electrode base materials 20 were bonded together so that the connection portions “a” of the first electrode layers and the connection portions “b” of the second electrode layers of adjacent dye-sensitized solar cells were connected to each other through the conductive adhesive and, as shown in FIG. 8C, regions S enclosed by a bold line functioned as the end regions. In this way, a dye-sensitized solar cell module 100 was produced.

FIG. 8C is a schematic plan view of the dye-sensitized solar cell module produced in Example 1.

<Sealing>

The thus produced dye-sensitized solar cell module was sandwiched between filling materials and subjected to lamination at 150° C. for sealing.

<Evaluation of Battery Performance>

The current-voltage characteristics of the thus produced dye-sensitized solar cell module were measured by applying a voltage using artificial sunlight (AM 1.5, incident light intensity: 100 mW/cm²) entering from the counter electrode side as alight source and a source measure unit (Keithley 2400 type). As a result, the dye-sensitized solar cell module had characteristics of short-circuit current of 23 (mA), open-circuit voltage of 6.1 (V), fill factor of 0.24, and maximum output of 32 mW. When a fluorescent lamp (500 lux) was used as a light source, characteristics of short-circuit current of 0.25 (mA), open-circuit voltage of 4.7 (V), fill factor of 0.70, and maximum output of 0.8 mW were achieved.

Further, the dye-sensitized solar cell module was bent 10 times, but short-circuit did not occur in any of its dye-sensitized solar cells.

### REFERENCE SIGNS LIST

1 Dye-sensitized solar cell
3 Porous layer
4 Solid electrolyte layer
5 Catalyst layer
10 First electrode base material
11 First base material
12 First electrode layer
20 Second electrode base material
20′ Second electrode base material substrate
100 Dye-sensitized solar cell module

What is claimed is:

1. A dye-sensitized solar cell module comprising:
a first electrode base material having one first base material and a plurality of first electrode layers formed in a pattern on the first base material;
a plurality of second electrode base materials each having at least a second electrode layer;
a plurality of porous layers provided either on the first electrode layers of the first electrode base material or on the second electrode layers of the second electrode base materials and containing a dye-sensitizer-supported fine particle of a metal oxide semiconductor; and
a plurality of solid electrolyte layers provided between the porous layers and the first electrode layers of the first electrode base material or the second electrode layers of the second electrode base materials, on which the porous layers are not provided, and containing a redox couple,
wherein a plurality of dye-sensitized solar cells each including the first electrode layer, the second electrode layer, the porous layer, and the solid electrolyte layer are connected to each other so that the first electrode layer of one of the adjacent dye-sensitized solar cells and the second electrode layer of another of the adjacent dye-sensitized solar cells are electrically connected to each other, and
wherein the dye-sensitized solar cells have, on an outside of an end of the first electrode layer of the first electrode base material, an end region including the first base material, the solid electrolyte layer, and the second electrode layer.

2. The dye-sensitized solar cell module according to claim 1, wherein, in each of the end regions, the solid electrolyte layer is provided at an end of the second electrode layer.

3. The dye-sensitized solar cell module according to claim 1, wherein the solid electrolyte layers are larger in width than the first electrode layers.
